(19) United States
(12) Patent Application Publication
(10) Pub. No.: US 2026/0052711 A1
(43) Pub. Date: Feb. 19, 2026

(54) CONDUCTIVE STRUCTURE INCLUDING CAPACITOR STRUCTURE AND METHOD FOR MANUFACTURING THE SAME

(71) Applicant: NANYA TECHNOLOGY CORPORATION, NEW TAIPEI CITY (TW)

(72) Inventor: JR-CHIUAN WANG, NEW TAIPEI CITY (TW)

(21) Appl. No.: 18/804,397

(22) Filed: Aug. 14, 2024

(51) Int. Cl. H01L 23/522; H10B 12/00

(52) U.S. Cl. CPC H10D 1/696; H01L 23/5223; H10B 12/03; H10B 12/315

(57) ABSTRACT

A conductive structure and a method of manufacturing a conductive structure are provided. The conductive structure includes a first support layer, a second support layer, a first electrode layer, an intermediate dielectric layer and a second electrode layer. The second support layer is disposed over and spaced apart from the first support layer. The first electrode layer includes a first part. The first part includes a first portion contacting the first support layer and a second portion contacting the second support layer. A thickness of the first portion is substantially equal to a thickness of the second portion. The intermediate dielectric layer is disposed on the first electrode layer. The second electrode layer is disposed on the intermediate dielectric layer.

### TECHNICAL FIELD

The present disclosure relates to a conductive structure and a method for manufacturing a conductive structure, and more particularly, to a conductive structure including a capacitor structure and a method for manufacturing the same.

### DISCUSSION OF THE BACKGROUND

To accomplish high integration density of an electronic element (e.g., a capacitor), dimensions of conductive vias of the electronic element are reduced, and an aspect ratio (height/width) of the conductive vias is increased. The conductive via may be formed by forming a thin conductive layer on a sidewall of a hole. During a subsequent etching process, a portion of the thin conductive layer on the sidewall of the hole may be damaged or broken. The broken segment of the thin conductive layer will cause a short circuit between adjacent conductive vias.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a conductive structure. The conductive structure includes a first support layer, a second support layer, a first electrode layer, an intermediate dielectric layer and a second electrode layer. The second support layer is disposed over and spaced apart from the first support layer. The first electrode layer includes a first part. The first part includes a first portion contacting the first support layer and a second portion contacting the second support layer. A thickness of the first portion is substantially equal to a thickness of the second portion. The intermediate dielectric layer is disposed on the first electrode layer. The second electrode layer is disposed on the intermediate dielectric layer.

Another aspect of the present disclosure provides a conductive structure. The conductive structure includes a first support layer, a second support layer, a first electrode layer, an intermediate dielectric layer and a second electrode layer. The second support layer is disposed over and spaced apart from the first support layer. The first electrode layer includes a first part and a second part substantially parallel with the first part. The first part and the second part contact the first support layer. The first part includes an upper portion higher than the second part. The upper portion of the first part of the first electrode layer has a first lateral surface contacting the second support layer and a second lateral surface opposite to the first lateral surface. The second lateral surface of the upper portion of the first part is an unetched surface. A top surface of the second part is an etched surface. The intermediate dielectric layer is disposed on the first electrode layer. The second electrode layer is disposed on the intermediate dielectric layer.

Another aspect of the present disclosure provides a method of manufacturing a conductive structure. The method includes providing a base material including a first support layer, a second support layer, and a sacrifice material between the first support layer and the second support layer. The method also includes forming a plurality of holes extending through the second support layer and extending into the first support layer. The method also includes forming a first electrode layer in the plurality of holes. The method also includes forming a plurality of buffer materials in the plurality of holes to cover the first electrode layer. The method also includes removing portions of the second support layer, portions of the first electrode layer and portions of the plurality of buffer materials to form a plurality of openings to extend through the second support layer and expose the plurality of buffer materials and the sacrifice material. The method also includes removing the plurality of buffer materials and the sacrifice material through the openings. The method also includes forming an intermediate dielectric layer on the first electrode layer. The method also includes forming a second electrode layer on the intermediate dielectric layer.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method for manufacturing a conductive structure in accordance with one embodiment of the present disclosure.

FIGS. 2 to 12B illustrate, in schematic diagrams, a flow for manufacturing a conductive structure in accordance with one embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

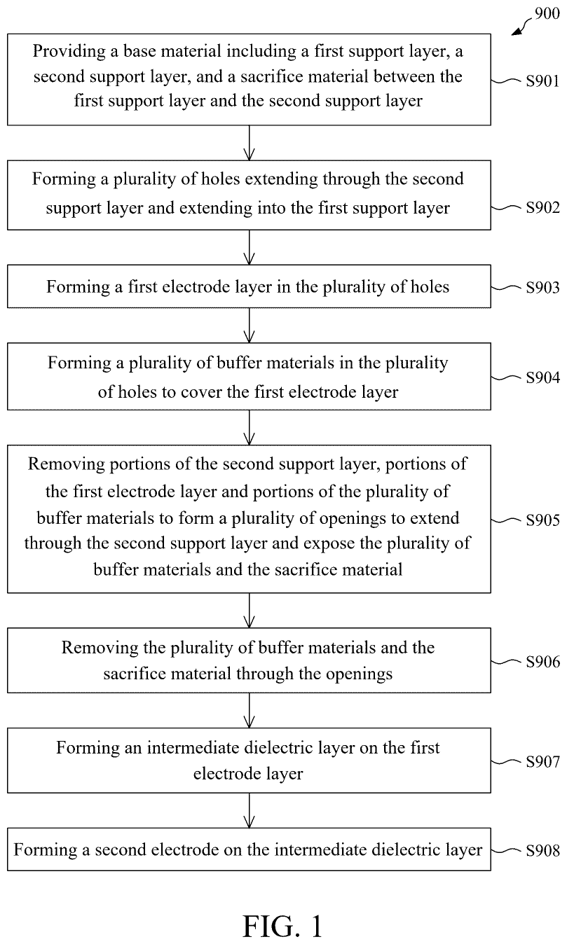

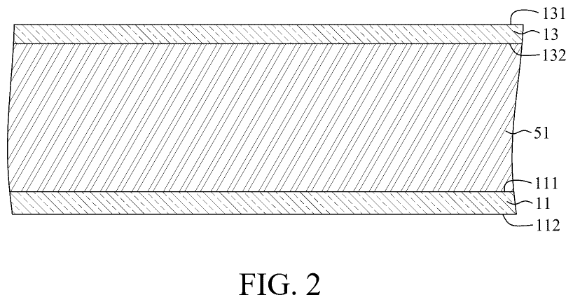

FIG. 1 illustrates, in a flowchart diagram form, a method 900 for manufacturing a conductive structure 1 in accordance with one embodiment of the present disclosure. FIGS. 2 to 12B illustrate stages of a method for manufacturing the conductive structure 1 in accordance with one embodiment of the present disclosure. At least some of these figures have been simplified for a better understanding of the aspects of the present disclosure.

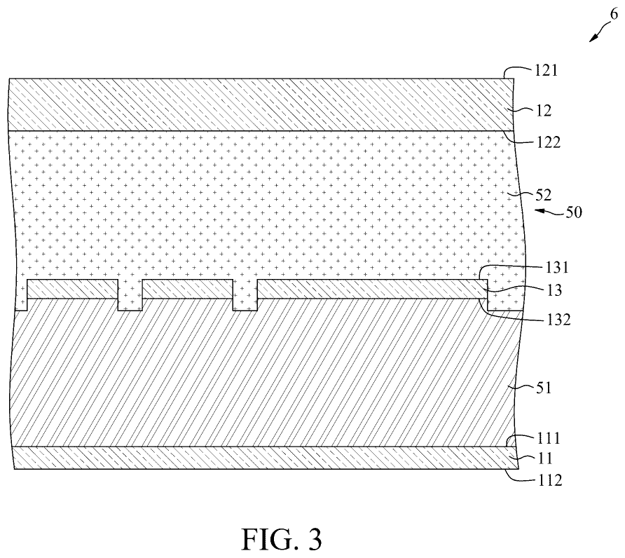

With reference to FIGS. 2 to 3, at step S901, a base material 6 may be provided.

Referring to FIG. 2, a lower sacrifice material 51 may be formed or disposed on a first support layer 11. A third support layer 13 may be formed or disposed on the lower sacrifice material 51. The lower sacrifice material 51 may be also referred to as “a first sacrifice layer” or “a bottom sacrifice layer”. The first support layer 11 may be also referred to as “a lower support layer” or “a bottom support layer”. The third support layer 13 may be also referred to as “a middle support layer” or “an intermediate support layer”. In some embodiments, the first support layer 11 may be formed or disposed on a top surface of a conductive layer. The conductive layer may include a suitable conductive material. For example, the conductive layer may include tungsten (W), copper (Cu), aluminum (Al), silver (Ag), an alloy thereof, or a combination thereof.

The first support layer 11 may have a top surface 111 and a bottom surface 112 opposite to the top surface 111. The bottom surface 112 of the first support layer 11 may face and contact the top surface of the conductive layer. For example, the first support layer 11 may be a dielectric layer or an insulation layer, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof.

The lower sacrifice material 51 may be formed or disposed on the top surface 111 of the first support layer 11. The lower sacrifice material 51 may directly contact the top surface 111 of the first support layer 11. The lower sacrifice material 51 may include a dielectric material or an insulation material, such as nitride, oxide, oxynitride amorphous silicon, polycrystalline silicon, or other suitable another. For example, the lower sacrifice material 51 may include boron phosphorus silicate glass (BPSG) that is an oxide doped with boron and phosphorus. The lower sacrifice material 51 may be formed by deposition. The material of the lower sacrifice material 51 is different from the material of the first support layer 11.

The third support layer 13 may be formed or disposed on the lower sacrifice material 51. Thus, the third support layer 13 may be disposed over and spaced apart from the first support layer 11. The third support layer 13 may have a top surface 131 and a bottom surface 132 opposite to the top surface 131. The bottom surface 132 of the third support layer 13 may face and contact the top surface of the lower sacrifice material 51. For example, the third support layer 13 may be a dielectric layer or an insulation layer, and may include silicon nitride (Si3N4, or SiN), silicon dioxide (SiO2), silicon oxynitride (N2OSi2), silicon nitride oxide (SiON), tantalum pentoxide (Ta2O5), aluminum oxide (Al2O3), strontium bismuth tantalum oxide (SrBi2Ta2O9, SBT), barium strontium titanate oxide (BaSrTiO3, BST), or a combination thereof. The material of the third support layer 13 may be different from the material of the lower sacrifice material 51. The material of the third support layer 13 may be same as or different from the material of the first support layer 11.

Referring to FIG. 3, the third support layer 13 may be patterned. That is, portions of the third support layer 13 may be removed to expose portions of the lower sacrifice material 51. Then, an upper sacrifice material 52 may be formed or disposed on the third support layer 13. Thus, a portion of the upper sacrifice material 52 may contact a portion of the lower sacrifice material 51. The upper sacrifice material 52 may partially contact the lower sacrifice material. Then, a second support layer 12 may be formed or disposed on the upper sacrifice material 52. The upper sacrifice material 52 may be also referred to as “a second sacrifice layer” or “a top sacrifice layer”. The second support layer 12 may be also referred to as “an upper support layer” or “a top support layer”.

The upper sacrifice material 52 may be formed or disposed on the top surface 131 of the third support layer 13. The upper sacrifice material 52 may directly contact the top surface 131 of the third support layer 13. The upper sacrifice material 52 may include a dielectric material or an insulation material, such as nitride, oxide, oxynitride amorphous silicon, polycrystalline silicon, or other suitable another. For example, the upper sacrifice material 52 may include boron phosphorus silicate glass (BPSG) that is an oxide doped with boron and phosphorus. The upper sacrifice material 52 may be formed by deposition. The material of the upper sacrifice material 52 may be the same as or different from the material of the lower sacrifice material 51.

The second support layer 12 may be formed or disposed on the upper sacrifice material 52. Thus, the second support layer 12 may be disposed over and spaced apart from the third support layer 13 and the first support layer 11. The second support layer 12 may have a top surface 121 and a bottom surface 122 opposite to the top surface 121. The bottom surface 122 of the second support layer 12 may face and contact the top surface of the upper sacrifice material 52. For example, the second support layer 12 may be a dielectric layer or an insulation layer, and may include silicon nitride (Si3N4, or SiN), silicon dioxide (SiO2), silicon oxynitride (N2OSi2), silicon nitride oxide (SiON), tantalum pentoxide (Ta2O5), aluminum oxide (Al2O3), strontium bismuth tantalum oxide (SrBi2Ta2O9, SBT), barium strontium titanate oxide (BaSrTiO3, BST), or a combination thereof. The material of the second support layer 12 may be same as or different from the material of the first support layer 11. The thickness of the second support layer 12 may be greater than the thickness of the first support layer 11 and the thickness of the third support layer 13.

Meanwhile, a base material 6 may be provided. The base material 6 may include the first support layer 11, the second support layer 12 and a sacrifice material 50 (including the lower sacrifice material 51 and the upper sacrifice material 52) between the first support layer 11 and the second support layer 12. In some embodiments, the base material 6 may include the first support layer 11, the lower sacrifice material 51, the third support layer 13, the upper sacrifice material 52 and the second support layer 12. The lower sacrifice material 51 may be disposed between the first support layer 11 and the third support layer 13. The upper sacrifice material 52 may be disposed between the third support layer 13 and the second support layer 12.

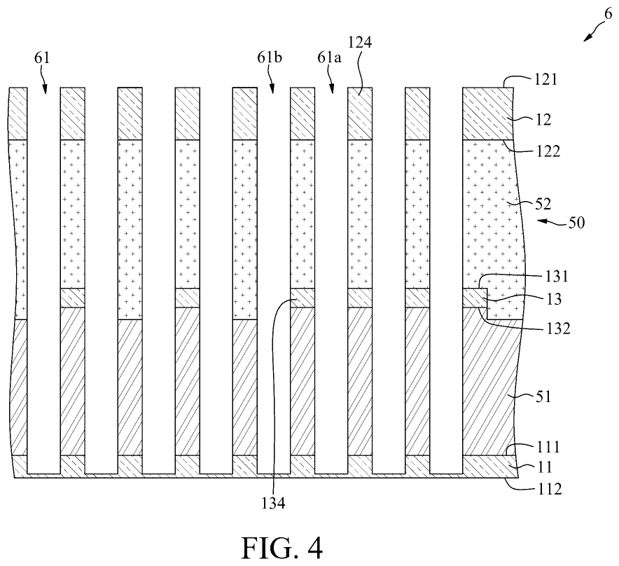

Referring to FIG. 4, at step S902, a plurality of holes 61 may be formed in the base material 6. The holes 61 may extend through the second support layer 12 and may extend into the first support layer 11. Thus, the holes 61 may extend through the second support layer 12, the upper sacrifice material 52, the third support layer 13 and the lower sacrifice material 51. The holes 61 may not extend through the first support layer 11. Thus, in the cross-sectional view, the second support layer 12 may include a plurality of portions 124, and the third support layer 13 may include a plurality of portions 134. That is, the holes 61 may be stopped by the first support layer 11. In some embodiments, the holes 61 may be formed by photography and etching process from the top surface 121 of the second support layer 12. The holes 61 may taper toward the first support layer 11. In some embodiments, the holes 61 may include a first hole 61a and a second hole 61b.

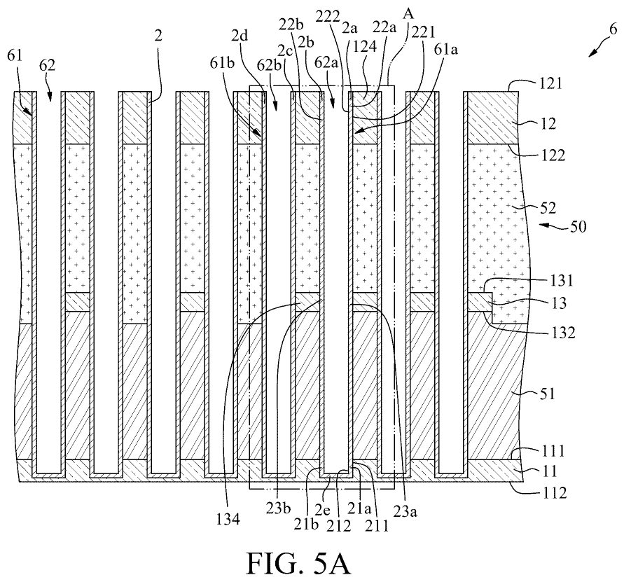

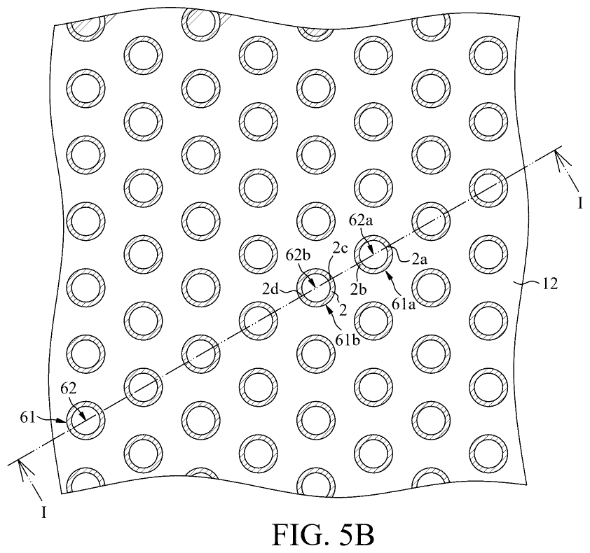

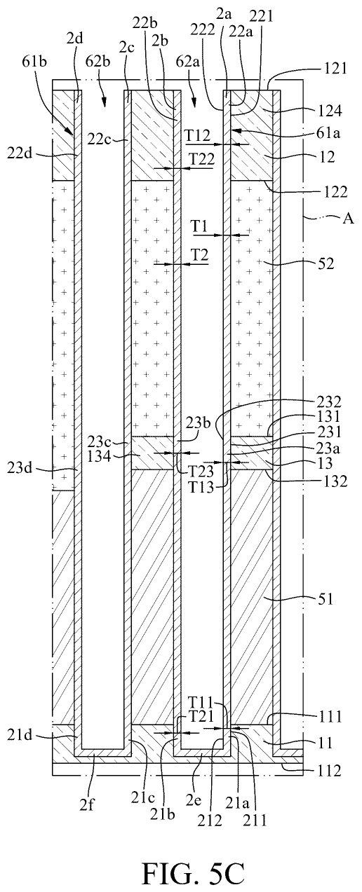

Referring to FIGS. 5A, 5B and 5C, at step S903, a first electrode layer 2 may be formed or disposed in the holes 61. FIG. 5B may illustrate a top view of FIG. 5A. Alternatively, FIG. 5A may illustrate a cross-sectional view of FIG. 5B taken along line I-I. FIG. 5C illustrates an enlarged view of an area “A” of FIG. 5A.

The first electrode layer 2 may be formed or disposed on the inner side walls of the holes 61 to define a plurality of central holes 62 in the holes 61. The first electrode layer 2 may include a conductive metal such as titanium nitride (TiN), titanium silicon nitride (TiSiN) or copper. The first electrode layer 2 may be formed by deposition. The first electrode layer 2 may have a substantially consistent thickness.

For example, the first electrode layer 2 may include a first part 2a, a second part 2b, a third part 2c, a fourth part 2d, a connecting part 2e and a connecting part 2f. The first part 2a, the second part 2b, the third part 2c and the fourth part 2d may be substantially parallel with and spaced apart from each other.

The first part 2a, the second part 2b and the connecting part 2e may be disposed in the first hole 61a. The first part 2a and the second part 2b may be disposed on the inner side wall of the first hole 61a. As shown in FIG. 5B, the first part 2a and the second part 2b may be two parts of a same ring shape. That is, the first part 2a of the first electrode layer 2 and the second part 2b of the first electrode layer 2 may collectively define a complete circle from the top view.

In addition, the connecting part 2e may be disposed on the bottom wall of the first hole 61a, and may connect the first part 2a and the second part 2b. The first part 2a, the second part 2b and the connecting part 2e may be formed concurrently and integrally to define a first central hole 62a in the first hole 61a.

The first part 2a may be disposed in the sacrifice material 50 (including the lower sacrifice material 51 and the upper sacrifice material 52) and may extend between the first support layer 11 and the second support layer 12. The first part 2a may include a first portion 21a (e.g., a lower portion), a second portion 22a (e.g., an upper portion) and a third portion 23a (e.g., a middle portion). The first portion 21a (e.g., the lower portion) may have a first lateral surface 211 and a second lateral surface 212 opposite to the first lateral surface 211. The first lateral surface 211 of the first portion 21a (e.g., the lower portion) may contact the first support layer 11 and the lower sacrifice material 51. The second lateral surface 212 of the first portion 21a (e.g., the lower portion) may face the first central hole 62a.

The second portion 22a (e.g., the upper portion) may have a first lateral surface 221 and a second lateral surface 222 opposite to the first lateral surface 221. The first lateral surface 221 of the second portion 22a (e.g., the upper portion) may contact the second support layer 12 and the upper sacrifice material 52. The second lateral surface 222 of the second portion 22a (e.g., the upper portion) may face the first central hole 62a.

The third portion 23a (e.g., the middle portion) may be disposed between the first portion 21a (e.g., the lower portion) and the second portion 22a (e.g., the upper portion). The third portion 23a (e.g., the middle portion) may have a first lateral surface 231 and a second lateral surface 232 opposite to the first lateral surface 231. The first lateral surface 231 of the third portion 23a (e.g., the middle portion) may contact the third support layer 13, the upper sacrifice material 52 and the lower sacrifice material 51. The second lateral surface 232 of the third portion 23a (e.g., the middle portion) may face the first central hole 62a.

The first lateral surface 211 of the first portion 21a of the first part 2a may be substantially aligned with the first lateral surface 221 of the second portion 22a of the first part 2a and the first lateral surface 231 of the third portion 23a of the first part 2a. Further, the second lateral surface 212 of the first portion 21a of the first part 2a may be substantially aligned with the second lateral surface 222 of the second portion 22a of the first part 2a and the second lateral surface 232 of the third portion 23a of the first part 2a. Thus, a thickness T11 of the first portion 21a is substantially equal to a thickness T12 of the second portion 22a and a thickness T13 of the third portion 23a. The thickness T11 of the first portion 21a, the thickness T12 of the second portion 22a and the thickness T13 of the third portion 23a is the thickness T1 of the first part 2a.

The second part 2b may be disposed in the sacrifice material 50 (including the lower sacrifice material 51 and the upper sacrifice material 52) and may extend between the first support layer 11 and the second support layer 12. The second part 2b may include a first portion 21b (e.g., a lower portion), a second portion 22b (e.g., an upper portion) and a third portion 23b (e.g., a middle portion). The first portion 21b (e.g., the lower portion) may have a first lateral surface and a second lateral surface opposite to the first lateral surface. The first lateral surface of the first portion 21b (e.g., the lower portion) may contact the first support layer 11 and the lower sacrifice material 51. The second lateral surface of the first portion 21b (e.g., the lower portion) may face the first central hole 62a.

The second portion 22b (e.g., the upper portion) may have a first lateral surface and a second lateral surface opposite to the first lateral surface. The first lateral surface of the second portion 22b (e.g., the upper portion) may contact the second support layer 12 and the upper sacrifice material 52. The second lateral surface of the second portion 22b (e.g., the upper portion) may face the first central hole 62a.

The third portion 23b (e.g., the middle portion) may be disposed between the first portion 21b (e.g., the lower portion) and the second portion 22b (e.g., the upper portion). The third portion 23b (e.g., the middle portion) may have a first lateral surface and a second lateral surface opposite to the first lateral surface. The first lateral surface of the third portion 23b (e.g., the middle portion) may contact the third support layer 13, the upper sacrifice material 52 and the lower sacrifice material 51. The second lateral surface of the third portion 23b (e.g., the middle portion) may face the first central hole 62a.

The first lateral surface of the first portion 21b of the second part 2b may be substantially aligned with the first lateral surface of the second portion 22b of the second part 2b and the first lateral surface of the third portion 23b of the second part 2b. Further, the second lateral surface of the first portion 21b of the second part 2b may be substantially aligned with the second lateral surface of the second portion 22b of the second part 2b and the second lateral surface of the third portion 23b of the second part 2b. Thus, a thickness T21 of the first portion 21b is substantially equal to a thickness T22 of the second portion 22b and a thickness T23 of the third portion 23b. The thickness T21 of the first portion 21b, the thickness T22 of the second portion 22b and the thickness T23 of the third portion 23b is the thickness T2 of the second part 2b. The thickness T2 of the second part 2b may be substantially equal to the thickness T1 of the first part 2a.

The third part 2c, the fourth part 2d and the connecting part 2f may be disposed in the second hole 61b. The third part 2c and the fourth part 2d may be disposed on the inner side wall of the second hole 61b. As shown in FIG. 5B, the third part 2c and the fourth part 2d may be two parts of a same ring shape. That is, the third part 2c of the first electrode layer 2 and the fourth part 2d of the first electrode layer 2 may collectively define a complete circle from the top view.

In addition, the connecting part 2f may be disposed on the bottom wall of the second hole 61b, and may connect the third part 2c and the fourth part 2d. The third part 2c, the fourth part 2d and the connecting part 2f may be formed concurrently and integrally to define a second central hole 62b in the second hole 61b.

The third part 2c may be disposed in the sacrifice material 50 (including the lower sacrifice material 51 and the upper sacrifice material 52) and may extend between the first support layer 11 and the second support layer 12. The third part 2c may include a first portion 21c (e.g., a lower portion), a second portion 22c (e.g., an upper portion) and a third portion 23c (e.g., a middle portion). The first portion 21c (e.g., the lower portion) may have a first lateral surface and a second lateral surface opposite to the first lateral surface. The first lateral surface of the first portion 21c (e.g., the lower portion) may contact the first support layer 11 and the lower sacrifice material 51. The second lateral surface of the first portion 21c (e.g., the lower portion) may face the second central hole 62b.

The second portion 22c (e.g., the upper portion) may have a first lateral surface and a second lateral surface opposite to the first lateral surface. The first lateral surface of the second portion 22c (e.g., the upper portion) may contact the second support layer 12 and the upper sacrifice material 52. The second lateral surface of the second portion 22c (e.g., the upper portion) may face the second central hole 62b.

The third portion 23c (e.g., the middle portion) may be disposed between the first portion 21c (e.g., the lower portion) and the second portion 22c (e.g., the upper portion). The third portion 23c (e.g., the middle portion) may have a first lateral surface and a second lateral surface opposite to the first lateral surface. The first lateral surface of the third portion 23c (e.g., the middle portion) may contact the third support layer 13, the upper sacrifice material 52 and the lower sacrifice material 51. The second lateral surface of the third portion 23c (e.g., the middle portion) may face the second central hole 62b.

The first lateral surface of the first portion 21c of the third part 2c may be substantially aligned with the first lateral surface of the second portion 22c of the third part 2c and the first lateral surface of the third portion 23c of the third part 2c. Further, the second lateral surface of the first portion 21c of the third part 2c may be substantially aligned with the second lateral surface of the second portion 22c of the third part 2c and the second lateral surface of the third portion 23c of the third part 2c. Thus, a thickness of the first portion 21c of the third part 2c is substantially equal to a thickness of the second portion 22c of the third part 2c and a thickness of the third portion 23c of the third part 2c. The thickness of the first portion 21c, the thickness of the second portion 22c and the thickness of the third portion is the thickness of the third part 2c.

The fourth part 2d may be disposed in the sacrifice material 50 (including the lower sacrifice material 51 and the upper sacrifice material 52) and may extend between the first support layer 11 and the second support layer 12. The fourth part 2d may include a first portion 21d (e.g., a lower portion), a second portion 22d (e.g., an upper portion) and a third portion 23d (e.g., a middle portion). The first portion 21d (e.g., the lower portion) may have a first lateral surface and a second lateral surface opposite to the first lateral surface. The first lateral surface of the first portion 21d (e.g., the lower portion) may contact the first support layer 11 and the lower sacrifice material 51. The second lateral surface of the first portion 21d (e.g., the lower portion) may face the second central hole 62b.

The second portion 22d (e.g., the upper portion) may have a first lateral surface and a second lateral surface opposite to the first lateral surface. The first lateral surface of the second portion 22d (e.g., the upper portion) may contact the second support layer 12 and the upper sacrifice material 52. The second lateral surface of the second portion 22d (e.g., the upper portion) may face the second central hole 62b.

The third portion 23d (e.g., the middle portion) may be disposed between the first portion 21d (e.g., the lower portion) and the second portion 22d (e.g., the upper portion). The third portion 23d (e.g., the middle portion) may have a first lateral surface and a second lateral surface opposite to the first lateral surface. The first lateral surface of the third portion 23d (e.g., the middle portion) may contact the upper sacrifice material 52 and the lower sacrifice material 51. The second lateral surface of the third portion 23d (e.g., the middle portion) may face the second central hole 62b.

The first lateral surface of the first portion 21d of the fourth part 2d may be substantially aligned with the first lateral surface of the second portion 22d of the fourth part 2d and the first lateral surface of the third portion 23d of the fourth part 2d. Further, the second lateral surface of the first portion 21d of the fourth part 2d may be substantially aligned with the second lateral surface of the second portion 22d of the fourth part 2d and the second lateral surface of the third portion 23d of the fourth part 2d. Thus, a thickness of the first portion 21d is substantially equal to a thickness of the second portion 22d and a thickness of the third portion 23d. The thickness of the first portion 21d, the thickness of the second portion 22d and the thickness of the third portion 23d is the thickness of the fourth part 2d. The thickness of the fourth part 2d may be substantially equal to the thickness of the third part 2c.

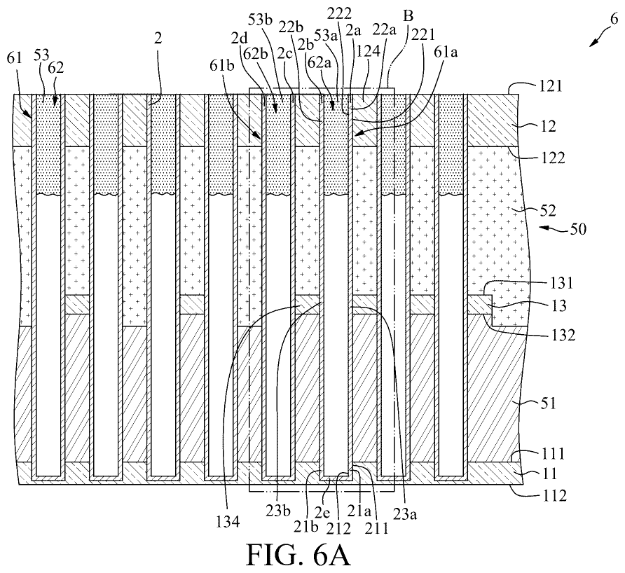

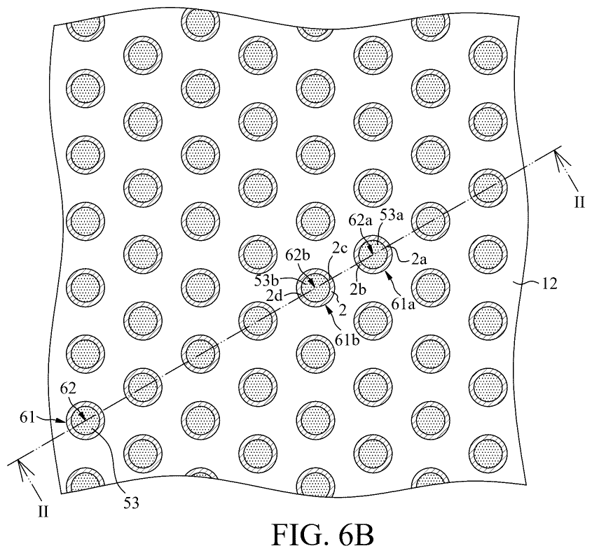

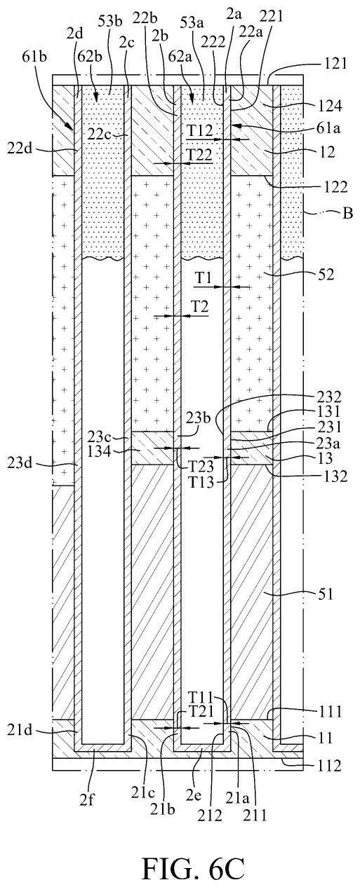

Referring to FIGS. 6A, 6B and 6C, at step S904, a plurality of buffer materials 53 may be formed or disposed in the holes 61 (e.g., in the central holes 62 such as the first central hole 62a and the second central hole 62b) to cover the first electrode layer 2. FIG. 6B may illustrate a top view of FIG. 6A. Alternatively, FIG. 6A may illustrate a cross-sectional view of FIG. 6B taken along line II-II. FIG. 6C illustrates an enlarged view of an area “B” of FIG. 6A.

The buffer material 53 may include a dielectric material or an insulation material, such as nitride, oxide, oxynitride amorphous silicon, polycrystalline silicon, or other suitable another. For example, the buffer material 53 may include boron phosphorus silicate glass (BPSG) that is an oxide doped with boron and phosphorus. The buffer material 53 may be formed by deposition. The material of the buffer material 53 may be the same as or different from the material of the upper sacrifice material 52.

In some embodiments, the buffer materials 53 may include a first buffer material 53a and a second buffer materials 53b. The first buffer material 53a may be formed or disposed in the first central hole 62a within the first hole 61a. The second buffer material 53b may be formed or disposed in the second central hole 62b within the second hole 61b. In some embodiments, the buffer materials 53 may not fill the central holes 62 completely. For example, the first buffer material 53a may not fill the first central hole 62a completely. The second buffer material 53b may not fill the second central hole 62b completely.

In the first central hole 62a, the first buffer material 53a may cover and protect the second lateral surface 222 of the second portion 22a of the first part 2a and the second lateral surface of the second portion 22b of the second part 2b. In the second central hole 62b, the second buffer material 53b may cover and protect the second lateral surface of the second portion 22c of the third part 2c and the second lateral surface of the second portion 22d of the fourth part 2d.

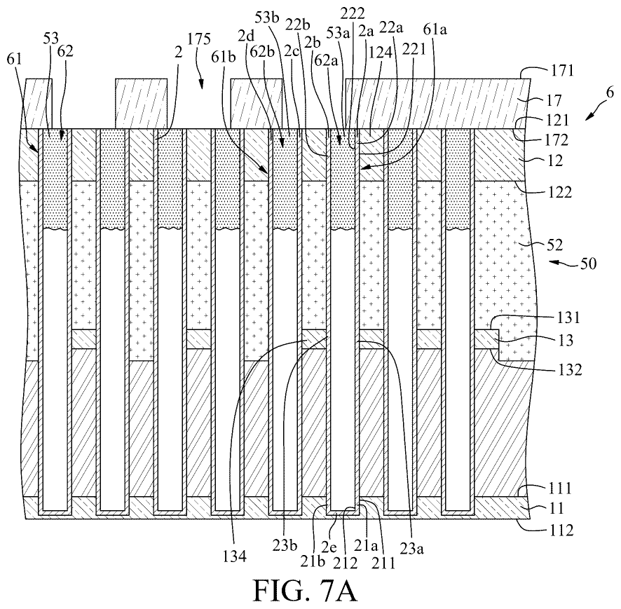

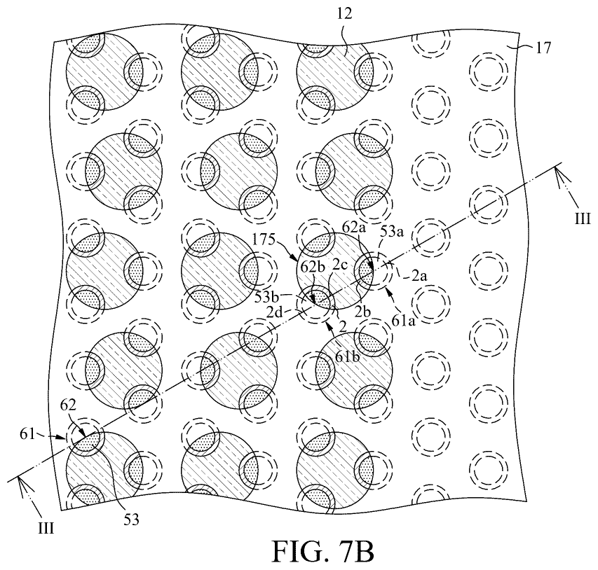

Referring to FIGS. 7A and 7B, a cap layer 17 may be formed or disposed on the top surface 121 of the second support layer 12 of the base material 6 to cover and contact the second support layer 12, the first electrode layer 2 and the plurality of buffer materials 53. FIG. 7B may illustrate a top view of FIG. 7A. Alternatively, FIG. 7A may illustrate a cross-sectional view of FIG. 7B taken along line III-III.

The cap layer 17 may have a top surface 171 and a bottom surface 172 opposite to the top surface 171. The bottom surface 172 of the cap layer 17 may face and contact the top surface 121 of the second support layer 12. For example, the cap layer 17 may be a mask, and may be formed by deposition. For example, the cap layer 17 may include, for example, nitride, oxide, oxynitride amorphous silicon, polycrystalline silicon, or another material suitable for use in the required patterning operation. For example, the cap layer 17 may include SiN harkmask. In some embodiments, the cap layer 17 may be formed through, for example, a CVD operation, an LPCVD operation, a PECVD operation, other feasible operations, or a combination thereof.

The cap layer 17 may define a plurality of apertures 175 extending through the cap layer 17 through a photography process. The apertures 175 may expose portions of the plurality of buffer materials 53, the second part 2b of the first electrode layer 2, the third part 2c of the first electrode layer 2 and portions of the second support layer 12. It is contemplated that the number of the holes 61 that are overlapped by one aperture 175 is not limited. There may be two, four, five, or more holes 61 overlapped by one aperture 175.

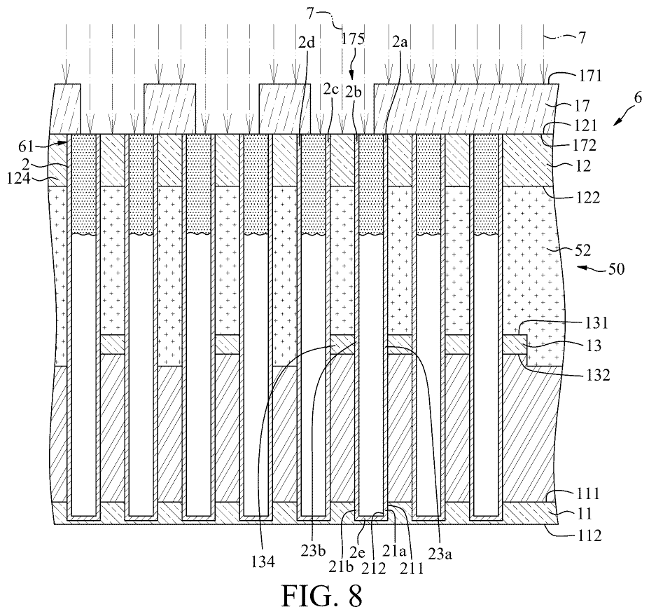

Referring to FIG. 8, an etching process may be conducted by using an etching agent 7. The etching process may be a dry etching process or a wet etching process. Thus, the etching agent 7 may be an etching gas, a plasma, an etching solution or an etching liquid. The etching agent 7 may be applied to the top surface 171 of the cap layer 17 and applied in the apertures 175. Thus, the etching agent 7 may etch the cap layer 17, the exposed portions of the buffer materials 53, the exposed second part 2b of the first electrode layer 2, the exposed third part 2c of the first electrode layer 2 and the exposed portions of the second support layer 12 simultaneously.

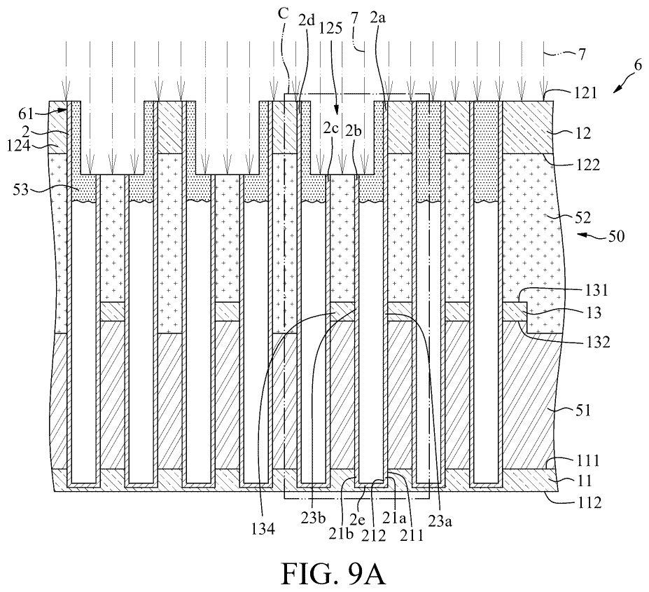

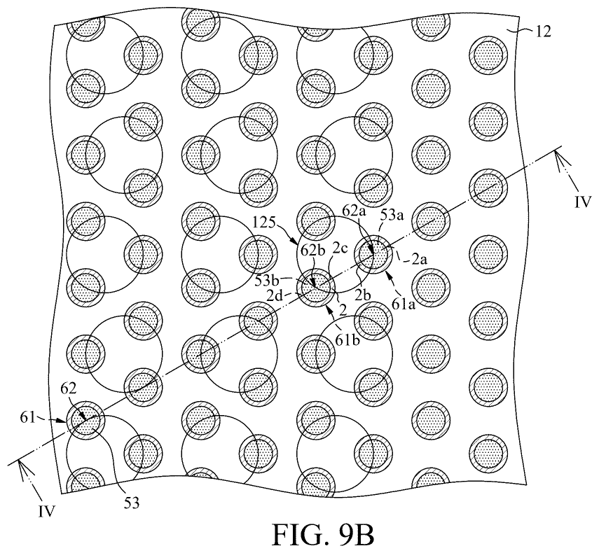

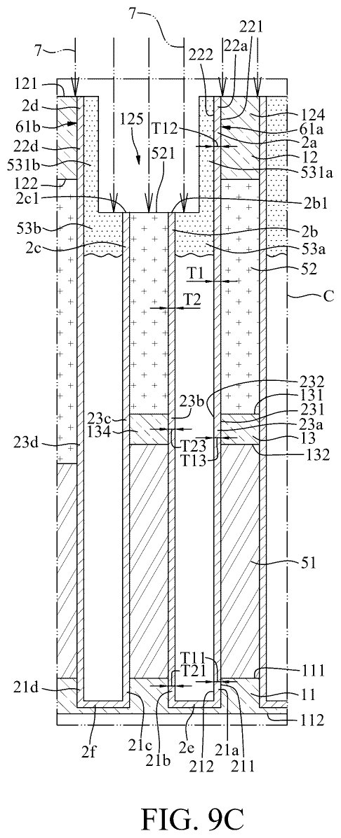

Referring to FIGS. 9A, 9B and 9C, at step S905, the etching process may continue. FIG. 9B may illustrate a top view of FIG. 9A. Alternatively, FIG. 9A may illustrate a cross-sectional view of FIG. 9B taken along line IV-IV. FIG. 9C illustrates an enlarged view of an area “C” of FIG. 9A.

During and after the etching process, the cap layer 17 may be removed. In addition, portions of the second support layer 12, portions of the first electrode layer 2 and portions of the plurality of buffer materials 53 may be removed so as to form a plurality of openings 125 to extend through the second support layer 12 and expose the plurality of buffer materials 53 and the sacrifice material 50 (e.g., the upper sacrifice material 52) by the etching process.

As shown in FIG. 9C, the upper sacrifice material 52 may have an inner top surface 521 exposed in the opening 125. The second part 2b of the first electrode layer 2 may have a top surface 2b1 exposed in the opening 125. The third part 2c of the first electrode layer 2 may have a top surface 2c1 exposed in the opening 125. A first remaining portion 531a of the first buffer material 53a may remain on the second lateral surface 222 of the second portion 22a of the first part 2a. A second remaining portion 531b of the second buffer material 53b may remain on the second lateral surface of the second portion 22d of the fourth part 2d.

The opening 125 may be defined by the first remaining portion 531a of the first buffer material 53a, the second remaining portion 531b of the second buffer material 53b, the inner top surface 521 of the upper sacrifice material 52, the top surface 2b1 of the second part 2b of the first electrode layer 2 and the top surface 2c1 of the third part 2c of the first electrode layer 2. The opening 125 does not expose the second lateral surface 222 of the second portion 22a of the first part 2a and the second lateral surface of the second portion 22d of the fourth part 2d. In addition, the second portion 22a of the first part 2a may be higher than the top surface 2b1 of the second part 2b. The second portion 22d of the fourth part 2d may be higher than the top surface 2c1 of the third part 2c. Therefore, the openings 125 may be stopped by the buffer material 53 (e.g., the first buffer material 53a and the second buffer material 53b). The openings 125 may taper downward.

As shown in FIG. 9B, the opening 125 may not be at a middle position between two holes 61 (e.g., the first hole 61a and the second hole 61b). Thus, a portion of the second part 2b and the third part 2c may be removed during the formation of the opening 125. As shown in FIG. 9B, the opening 125 may overlap three holes 61 from a top view. It is contemplated that the number of the holes 61 that are overlapped by one opening 125 is not limited. There may be two, four, five, or more holes 61 overlapped by one opening 125.

During the etching process, the first remaining portion 531a of the first buffer material 53a may prevent the second lateral surface 222 of the second portion 22a of the first part 2a from being etched or damaged by the etching agent 7. Thus, the second lateral surface 222 of the second portion 22a of the first part 2a is an unetched surface. The first part 2a may have a consistent thickness T1. That is, the thickness T12 of the second portion 22a of the first part 2a will not reduce after the etching process. The thickness T12 of the second portion 22a of the first part 2a will still be substantially equal to the thickness T11 of the first portion 21a and the thickness T13 of the third portion 23a after the etching process.

In addition, a surface condition (e.g., surface roughness) of the second lateral surface 212 of the first portion 21a of the first part 2a may be substantially same as a surface condition (e.g., surface roughness) of the second lateral surface 222 of the second portion 22a of the first part 2a.

The top surface 2b1 of the second part 2b may be etched by the etching agent 7. Thus, the top surface 2b1 of the second part 2b may be an etched surface. A surface condition (e.g., surface roughness) of the top surface 2b1 of the second part 2b of the first electrode layer 2 may be different from the surface condition (e.g., surface roughness) of the second lateral surface 222 of the second portion 22a of the first part 2a. The top surface 2b1 of the second part 2b may be lower than the bottom surface 122 of the second support layer 12. The second part 2b may be free from contacting the second support layer 12.

Similarly, during the etching process, the second remaining portion 531b of the second buffer material 53b may prevent the second lateral surface of the second portion 22d of the fourth part 2d from being etched or damaged by the etching agent 7. Thus, the second lateral surface of the second portion 22d of the fourth part 2d is an unetched surface. The fourth part 2d may have a consistent thickness. That is, the thickness of the second portion 22d of the fourth part 2d will not reduce after the etching process. The thickness of the second portion 22d of the fourth part 2d will still be substantially equal to the thickness of the first portion 21d and the thickness of the third portion 23d after the etching process.

In addition, a surface condition (e.g., surface roughness) of the second lateral surface of the first portion 21d of the fourth part 2d may be substantially same as a surface condition (e.g., surface roughness) of the second lateral surface of the second portion 22d of the fourth part 2d.

The top surface 2c1 of the third part 2c may be etched by the etching agent 7. Thus, the top surface 2c1 of the third part 2c may be an etched surface. A surface condition (e.g., surface roughness) of the top surface 2c1 of the third part 2d of the first electrode layer 2 may be different from the surface condition (e.g., surface roughness) of the second lateral surface of the second portion 22d of the fourth part 2d. The top surface 2c1 of the third part 2c may be lower than the bottom surface 122 of the second support layer 12. The third part 2c may be free from contacting the second support layer 12.

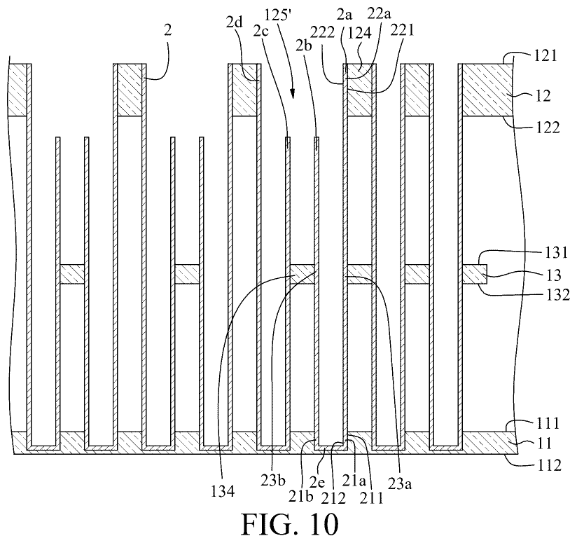

Referring to FIG. 10, at step S906, the buffer materials 53 (e.g., the first buffer material 53a and the second buffer material 53b) and the sacrifice material 50 (including the lower sacrifice material 51 and the upper sacrifice material 52) may be removed by applying an etchant through the openings 125. For example, the buffer materials 53 and the sacrifice material 50 may be removed simultaneously or concurrently by a wet etching process or a stripping process.

Meanwhile, the openings 125 of FIG. 9A become the openings 125′ of FIG. 10. The openings 125′ of FIG. 10 may be defined by the second support layer 12 and a portion of the first electrode layer 2. The second lateral surface 222 of the second portion 22a of the first part 2a of the first electrode layer 2 faces the opening 125′ defined by the second support layer 12 and a portion of the first electrode layer 2. The second lateral surface of the second portion 22d of the fourth part 2d of the first electrode layer 2 faces the opening 125′. The second part 2b and the third part 2c are disposed under the opening 125′. A portion 134 of the third support layer 13 is disposed under the opening 125′ of the second support layer 12.

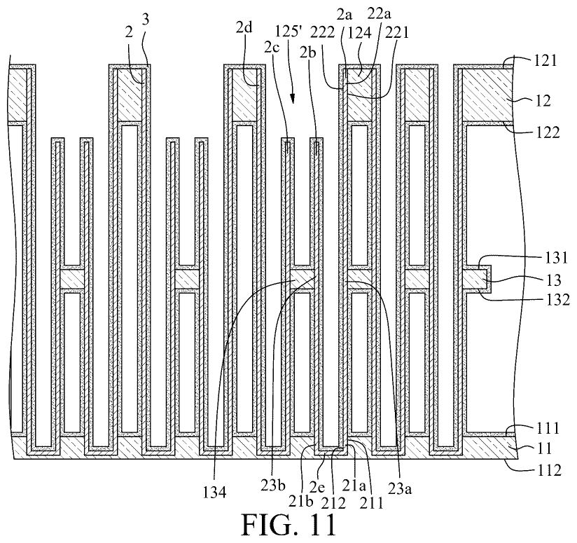

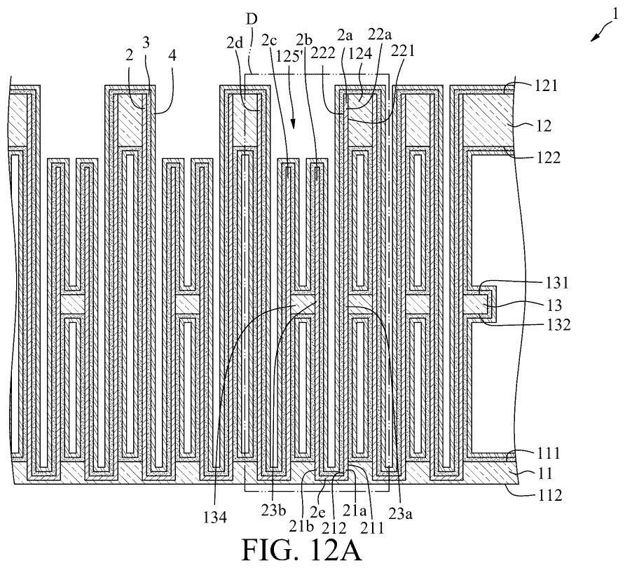

Referring to FIG. 11, at step S907, an intermediate dielectric layer 3 may be formed or disposed on the first electrode layer 2. In some embodiments, the intermediate dielectric layer 3 may be conformal with the first electrode layer 2. In some embodiments, the intermediate dielectric layer 3 may be a high-k dielectric layer. In some embodiments, the intermediate dielectric layer 3 may be further formed or disposed on the side walls of the apertures 175 and the top surface 171 of the cap layer 17.

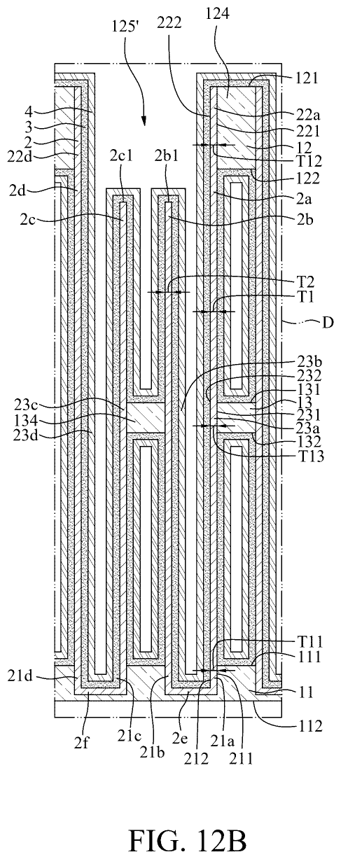

Referring to FIGS. 12A and 12B, at step S908, a second electrode layer 4 may be formed or disposed on the intermediate dielectric layer 3. FIG. 12B illustrates an enlarged view of an area “D” of FIG. 12A.

The second electrode layer 4 may be conformal with the intermediate dielectric layer 3. The second electrode layer 4 may include a conductive metal such as titanium nitride (TiN), titanium silicon nitride (TiSiN) or copper. The second electrode layer 4 may be formed by deposition. The material of the second electrode layer 4 may be same as or different from the material of the first electrode layer 2. The second electrode layer 4 may have a substantially consistent thickness. Meanwhile, a conductive structure 1 may be formed. The first electrode layer 2, the intermediate dielectric layer 3 and the second electrode layer 4 may collectively form a capacitor structure.

Referring to FIGS. 12A and 12B, a schematic cross-sectional view of a conductive structure 1 according to one embodiment of the present disclosure is illustrated. For example, the conductive structure 1 may include a capacitor structure of a memory cell. In some embodiments, the memory cell may include a dynamic random access memory cell (DRAM cell). In some embodiments, the conductive structure 1 may be a part of an interconnection structure over a substrate of a semiconductor device. It is contemplated that more inter-metal dielectric layers and the associated conductive layers and conductive vias may be formed over the conductive structure 1 and/or the capacitor structure.

In addition, the conductive structure 1 and/or the capacitor structure may be a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The conductive structure 1 may include a first support layer 11, a second support layer 12, a third support layer 13, a cap layer 17, a first electrode layer 2, an intermediate dielectric layer 3 and a second electrode layer 4. The first support layer 11 may be also referred to as “a lower support layer” or “a bottom support layer”. The second support layer 12 may be also referred to as “an upper support layer” or “a top support layer”. The third support layer 13 may be also referred to as “a middle support layer”or “an intermediate support layer”.

The first support layer 11 may have a top surface 111 and a bottom surface 112 opposite to the top surface 111. The bottom surface 112 of the first support layer 11 may face and contact the top surface of a conductive layer. The third support layer 13 may be disposed over and spaced apart from the first support layer 11.

The third support layer 13 may have a top surface 131 and a bottom surface 132 opposite to the top surface 131. The material of the third support layer 13 may be same as or different from the material of the first support layer 11. The third support layer 13 may be patterned to include a plurality of portions 134.

The second support layer 12 may be disposed over and spaced apart from the third support layer 13 and the first support layer 11. The third support layer 13 may be disposed between the first support layer 11 and the second support layer 12. The second support layer 12 may have a top surface 121 and a bottom surface 122 opposite to the top surface 121. The material of the second support layer 12 may be same as or different from the material of the first support layer 11. The thickness of the second support layer 12 may be greater than the thickness of the first support layer 11 and the thickness of the third support layer 13. The second support layer 12 may define a plurality of openings 125′.

The cap layer 17 may be disposed on the top surface 121 of the second support layer 12. The cap layer 17 may have a top surface 171 and a bottom surface 172 opposite to the top surface 171. The bottom surface 172 of the cap layer 17 may face and contact the top surface 121 of the second support layer 12. The cap layer 17 may define a plurality of apertures 175 extending through the cap layer 17. The apertures 175 of the cap layer 17 may be in communication with the openings 125′ of the second support layer 12.

The first electrode layer 2 may include a first part 2a, a second part 2b, a third part 2c, a fourth part 2d, a connecting part 2e and a connecting part 2f. The first part 2a, the second part 2b, the third part 2c and the fourth part 2d may be substantially parallel with and spaced apart from each other.

The first part 2a and the second part 2b may be two parts of a same ring shape. That is, the first part 2a of the first electrode layer 2 and the second part 2b of the first electrode layer 2 may collectively define a complete circle from the top view. In addition, the connecting part 2e may be disposed in the first support layer 11, and may connect the first part 2a and the second part 2b. The first part 2a, the second part 2b and the connecting part 2e may be formed concurrently.

The first part 2a may extend between the first support layer 11 and the second support layer 12. The first part 2a may include a first portion 21a (e.g., a lower portion), a second portion 22a (e.g., an upper portion) and a third portion 23a (e.g., a middle portion). The first portion 21a (e.g., the lower portion) may have a first lateral surface 211 and a second lateral surface 212 opposite to the first lateral surface 211. The first lateral surface 211 of the first portion 21a (e.g., the lower portion) may contact the first support layer 11.

The second portion 22a (e.g., the upper portion) may have a first lateral surface 221 and a second lateral surface 222 opposite to the first lateral surface 221. The first lateral surface 221 of the second portion 22a (e.g., the upper portion) may contact the second support layer 12. The second lateral surface 222 of the second portion 22a (e.g., the upper portion) may face the opening 125′ defined by the second support layer 12. The second lateral surface 222 of the second portion 22a of the first part 2a is an unetched surface.

In addition, a surface condition (e.g., surface roughness) of the second lateral surface 212 of the first portion 21a of the first part 2a may be substantially same as a surface condition (e.g., surface roughness) of the second lateral surface 222 of the second portion 22a of the first part 2a.

The third portion 23a (e.g., the middle portion) may be disposed between the first portion 21a (e.g., the lower portion) and the second portion 22a (e.g., the upper portion). The third portion 23a (e.g., the middle portion) may have a first lateral surface 231 and a second lateral surface 232 opposite to the first lateral surface 231. The first lateral surface 231 of the third portion 23a (e.g., the middle portion) may contact the third support layer 13.

The first lateral surface 211 of the first portion 21a of the first part 2a may be substantially aligned with the first lateral surface 221 of the second portion 22a of the first part 2a and the first lateral surface 231 of the third portion 23a of the first part 2a. Further, the second lateral surface 212 of the first portion 21a of the first part 2a may be substantially aligned with the second lateral surface 222 of the second portion 22a of the first part 2a and the second lateral surface 232 of the third portion 23a of the first part 2a. Thus, a thickness T11 of the first portion 21a is substantially equal to a thickness T12 of the second portion 22a and a thickness T13 of the third portion 23a. The thickness T11 of the first portion 21a, the thickness T12 of the second portion 22a and the thickness T13 of the third portion 23a is the thickness T1 of the first part 2a. The first part 2a of the first electrode layer 2 may have a substantially consistent thickness T1.

The second part 2b may include a first portion 21b (e.g., a lower portion) and a third portion 23b (e.g., a middle portion). The first portion 21b (e.g., the lower portion) may have a first lateral surface and a second lateral surface opposite to the first lateral surface. The first lateral surface of the first portion 21b (e.g., the lower portion) may contact the first support layer 11.

The third portion 23b (e.g., the middle portion) may be disposed on the first portion 21b (e.g., the lower portion). The third portion 23b (e.g., the middle portion) may have a first lateral surface and a second lateral surface opposite to the first lateral surface. The first lateral surface of the third portion 23b (e.g., the middle portion) may contact the third support layer 13.

The first lateral surface of the first portion 21b of the second part 2b may be substantially aligned with the first lateral surface of the third portion 23b of the second part 2b. Further, the second lateral surface of the first portion 21b of the second part 2b may be substantially aligned with the second lateral surface of the third portion 23b of the second part 2b. Thus, the second part 2b of the first electrode layer 2 may have a substantially consistent thickness T2. The thickness T2 of the second part 2b may be substantially equal to the thickness T1 of the first part 2a. That is, the thickness T2 of the second part 2b of the first electrode layer 2 may be substantially equal to the thickness T12 of the second portion 22a of the first part 2a of the first electrode layer 2.

The top surface 2b1 of the second part 2b may be etched during the etching process. Thus, the top surface 2b1 of the second part 2b may be an etched surface. A surface condition (e.g., surface roughness) of the top surface 2b1 of the second part 2b of the first electrode layer 2 may be different from the surface condition (e.g., surface roughness) of the second lateral surface 222 of the second portion 22a of the first part 2a of the first electrode layer 2. The top surface 2b1 of the second part 2b may be lower than the bottom surface 122 of the second support layer 12. The second part 2b may be free from contacting the second support layer 12. The second part 2b may be disposed under the opening 125′. A portion 134 of the third support layer 13 may be disposed under the opening 125′ of the second support layer 12.

The third part 2c and the fourth part 2d may be two parts of a same ring shape. That is, the third part 2c of the first electrode layer 2 and the fourth part 2d of the first electrode layer 2 may collectively define a complete circle from the top view. In addition, the connecting part 2f may be disposed in the first support layer 11, and may connect the third part 2c and the fourth part 2d. The third part 2c, the fourth part 2d and the connecting part 2f may be formed concurrently.

The third part 2c may extend between the first support layer 11 and the second support layer 12. The third part 2c may include a first portion 21c (e.g., a lower portion) and a third portion 23c (e.g., a middle portion). The first portion 21c (e.g., the lower portion) may have a first lateral surface and a second lateral surface opposite to the first lateral surface. The first lateral surface of the first portion 21c (e.g., the lower portion) may contact the first support layer 11.

The third portion 23c (e.g., the middle portion) may be disposed between on the first portion 21c (e.g., the lower portion). The third portion 23c (e.g., the middle portion) may have a first lateral surface and a second lateral surface opposite to the first lateral surface. The first lateral surface of the third portion 23c (e.g., the middle portion) may contact the third support layer 13.

The first lateral surface of the first portion 21c of the third part 2c may be substantially aligned with the first lateral surface of the third portion 23c of the third part 2c. Further, the second lateral surface of the first portion 21c of the third part 2c may be substantially aligned with the second lateral surface of the third portion 23c of the third part 2c. Thus, the third part 2c of the first electrode layer 2 may have a substantially consistent thickness. The thickness of the third part 2c may be substantially equal to the thickness of the fourth part 2d.

The top surface 2c1 of the third part 2c may be etched during the etching process. Thus, the top surface 2c1 of the third part 2c may be an etched surface. A surface condition (e.g., surface roughness) of the top surface 2c1 of the third part 2c of the first electrode layer 2 may be different from the surface condition (e.g., surface roughness) of the second lateral surface of the second portion 22d of the fourth part 2d of the first electrode layer 2. The top surface 2c1 of the third part 2c may be lower than the bottom surface 122 of the second support layer 12. The third part 2c may be free from contacting the second support layer 12. The third part 2c may be disposed under the opening 125′. The top surface 2c1 of the third part 2c may substantially aligned with the top surface 2b1 of the second part 2b. Thus, a length of the third part 2c may be substantially equal to a length of the second part 2b.

The fourth part 2d may include a first portion 21d (e.g., a lower portion), a second portion 22d (e.g., an upper portion) and a third portion 23d (e.g., a middle portion). The first portion 21d (e.g., the lower portion) may have a first lateral surface and a second lateral surface opposite to the first lateral surface. The first lateral surface of the first portion 21d (e.g., the lower portion) may contact the first support layer 11.

The second portion 22d (e.g., the upper portion) may have a first lateral surface and a second lateral surface opposite to the first lateral surface. The first lateral surface of the second portion 22d (e.g., the upper portion) may contact the second support layer 12.

The third portion 23d (e.g., the middle portion) may be disposed between the first portion 21d (e.g., the lower portion) and the second portion 22d (e.g., the upper portion). The third portion 23d (e.g., the middle portion) may have a first lateral surface and a second lateral surface opposite to the first lateral surface. The first lateral surface of the third portion 23d (e.g., the middle portion) may contact the intermediate dielectric layer 3.

The first lateral surface of the first portion 21d of the fourth part 2d may be substantially aligned with the first lateral surface of the second portion 22d of the fourth part 2d and the first lateral surface of the third portion 23d of the fourth part 2d. Further, the second lateral surface of the first portion 21d of the fourth part 2d may be substantially aligned with the second lateral surface of the second portion 22d of the fourth part 2d and the second lateral surface of the third portion 23d of the fourth part 2d. Thus, a thickness of the first portion 21d is substantially equal to a thickness of the second portion 22d and a thickness of the third portion 23d. The thickness of the first portion 21d, the thickness of the second portion 22d and the thickness of the third portion 23d is the thickness of the fourth part 2d. The thickness of the fourth part 2d may be substantially equal to the thickness of the third part 2c.

The intermediate dielectric layer 3 may be disposed on the first electrode layer 2. In some embodiments, the intermediate dielectric layer 3 may be conformal with the first electrode layer 2. In some embodiments, the intermediate dielectric layer 3 may be a high-k dielectric layer. In some embodiments, the intermediate dielectric layer 3 may be further disposed on the side walls of the apertures 175 and the top surface 171 of the cap layer 17.

The second electrode layer 4 may be formed or disposed on the intermediate dielectric layer 3. The second electrode layer 4 may be conformal with the intermediate dielectric layer 3. The material of the second electrode layer 4 may be same as or different from the material of the first electrode layer 2. The second electrode layer 4 may have a substantially consistent thickness. The first electrode layer 2, the intermediate dielectric layer 3 and the second electrode layer 4 may collectively form a capacitor structure.

One aspect of the present disclosure provides a conductive structure. The conductive structure includes a first support layer, a second support layer, a first electrode layer, an intermediate dielectric layer and a second electrode layer. The second support layer is disposed over and spaced apart from the first support layer. The first electrode layer includes a first part. The first part includes a first portion contacting the first support layer and a second portion contacting the second support layer. A thickness of the first portion is substantially equal to a thickness of the second portion. The intermediate dielectric layer is disposed on the first electrode layer. The second electrode layer is disposed on the intermediate dielectric layer.

Another aspect of the present disclosure provides a conductive structure. The conductive structure includes a first support layer, a second support layer, a first electrode layer, an intermediate dielectric layer and a second electrode layer. The second support layer is disposed over and spaced apart from the first support layer. The first electrode layer includes a first part and a second part substantially parallel with the first part. The first part and the second part contact the first support layer. The first part includes an upper portion higher than the second part. The upper portion of the first part of the first electrode layer has a first lateral surface contacting the second support layer and a second lateral surface opposite to the first lateral surface. The second lateral surface of the upper portion of the first part is an unetched surface. A top surface of the second part is an etched surface. The intermediate dielectric layer is disposed on the first electrode layer. The second electrode layer is disposed on the intermediate dielectric layer.

Another aspect of the present disclosure provides a method of manufacturing a conductive structure. The method includes providing a base material including a first support layer, a second support layer, and a sacrifice material between the first support layer and the second support layer. The method also includes forming a plurality of holes extending through the second support layer and extending into the first support layer. The method also includes forming a first electrode layer in the plurality of holes. The method also includes forming a plurality of buffer materials in the plurality of holes to cover the first electrode layer. The method also includes removing portions of the second support layer, portions of the first electrode layer and portions of the plurality of buffer materials to form a plurality of openings to extend through the second support layer and expose the plurality of buffer materials and the sacrifice material. The method also includes removing the plurality of buffer materials and the sacrifice material through the openings. The method also includes forming an intermediate dielectric layer on the first electrode layer. The method also includes forming a second electrode layer on the intermediate dielectric layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A conductive structure, comprising:
a first support layer;
a second support layer disposed over and spaced apart from the first support layer;
a first electrode layer including a first part, wherein the first part includes a first portion contacting the first support layer and a second portion contacting the second support layer, wherein a thickness of the first portion is substantially equal to a thickness of the second portion;
an intermediate dielectric layer disposed on the first electrode layer; and
a second electrode layer disposed on the intermediate dielectric layer.

2. The conductive structure of claim 1, wherein in a cross-sectional view, the first part of the first electrode layer has a substantially consistent thickness.

3. The conductive structure of claim 1, wherein in a cross-sectional view, the second portion of the first part of the first electrode layer has a first lateral surface contacting the second support layer and a second lateral surface opposite to the first lateral surface, wherein the second lateral surface of the second portion of the first part is an unetched surface.

4. The conductive structure of claim 3, wherein in the cross-sectional view, the second lateral surface of the second portion of the first part faces an opening defined by the second support layer.

5. The conductive structure of claim 3, wherein the first portion of the first part of the first electrode layer has a first lateral surface contacting the first support layer and a second lateral surface opposite to the first lateral surface, wherein the second lateral surface of the first portion of the first part of the first electrode layer is substantially aligned with the second lateral surface of the second portion of the first part of the first electrode layer.

6. The conductive structure of claim 5, wherein a surface condition of the second lateral surface of the first portion of the first part of the first electrode layer is substantially same as a surface condition of the second lateral surface of the second portion of the first part of the first electrode layer.

7. The conductive structure of claim 6, wherein a surface roughness of the second lateral surface of the first portion of the first part of the first electrode layer is substantially equal to a surface roughness the second lateral surface of the second portion of the first part of the first electrode layer.

8. The conductive structure of claim 3, wherein the first electrode layer further includes a second part substantially parallel with and spaced apart from the first part, wherein a top surface of the second part is an etched surface.

9. The conductive structure of claim 8, wherein a surface condition of the top surface of the second part of the first electrode layer is different from a surface condition of the second lateral surface of the second portion of the first part of the first electrode layer.

10. The conductive structure of claim 8, wherein a surface roughness of the top surface of the second part of the first electrode layer is different from a surface roughness of the second lateral surface of the second portion of the first part of the first electrode layer.

11. The conductive structure of claim 8, wherein a thickness of the second part of the first electrode layer is substantially equal to a thickness of the second portion of the first part of the first electrode layer.

12. The conductive structure of claim 8, wherein the top surface of the second part is lower than a bottom surface of the second support layer.

13. The conductive structure of claim 8, wherein the second part is free from contacting the second support layer.

14. The conductive structure of claim 13, wherein the second part is disposed under an opening defined by the second support layer.

15. The conductive structure of claim 8, wherein the first part of the first electrode layer and the second part of the first electrode layer collectively define a complete circle from a top view.

16. The conductive structure of claim 1, further comprising a third support layer disposed between the first support layer and the second support layer, wherein the first part of the first electrode layer further includes a third portion contacting the third support layer, wherein a thickness of the third portion is substantially equal to a thickness of the second portion.

17. The conductive structure of claim 16, wherein in a cross-sectional view, the second portion of the first part of the first electrode layer has a first lateral surface contacting the second support layer and a second lateral surface opposite to the first lateral surface of the second portion, the third portion of the first part of the first electrode layer has a first lateral surface contacting the third support layer and a second lateral surface opposite to the first lateral surface of the third portion, wherein the second lateral surface of the second portion of the first part is substantially aligned with the second lateral surface of the third portion of the first part.

18. The conductive structure of claim 16, wherein a portion of the third support layer is disposed under an opening of the second support layer.
